(19) United States
(12) Patent Application Publication
(10) Pub. No.: US 2026/0025970 A1
(43) Pub. Date: Jan. 22, 2026

(54) TRANSISTOR MANUFACTURING METHOD

(71) Applicant: JUSUNG ENGINEERING CO., LTD., Gwangju-Si, Gyeonggi-Do (KR)

(72) Inventors: Du Ho KIM, Gwangju-Si, Gyeonggi-Do (KR); Duck Ho KIM, Gwangju-Si, Gyeonggi-Do (KR); Min Hyuk KIM, Gwangju-Si, Gyeonggi-Do (KR); Chang Kyun PARK, Gwangju-Si, Gyeonggi-Do (KR); Chul Joo HWANG, Gwangju-Si, Gyeonggi-Do (KR)

(21) Appl. No.: 18/859,812

(22) PCT Filed: Apr. 13, 2023
(86) PCT No.: PCT/KR2023/005031

§ 371 Date: Oct. 24, 2024

(30) Foreign Application Priority Data
Apr. 26, 2022 (KR) 10-2022-0051439
May 20, 2022 (KR) 10-2022-0062043

(51) Int. Cl. H10B 12/00

(52) U.S. Cl. CPC H10B 12/05; H10B 12/30

(57) ABSTRACT

Provided is a method for manufacturing a transistor, and more particularly, a method for manufacturing a transistor, which is performed to manufacture a transistor having improved characteristics. The method for manufacturing the transistor including a metal line and a channel layer includes preparing a substrate patterned to expose a first channel layer comprising metal oxide; and forming a second channel layer on an exposed surface of the first channel layer by using at least one of IGZO, IZO, InO, or ZnO.

### TECHNICAL FIELD

The present disclosure relates to a method of manufacturing a transistor and more particularly, to a method for manufacturing a transistor having improved characteristics.

### BACKGROUND ART

A transistor is used as a circuit for independently driving each cell or pixel in a semiconductor element, a liquid crystal display (LCD), an organic electroluminescence (EL) display, and the like.

The transistor is formed together with a gate line and a data line on a lower substrate of the display device. That is, the transistor is constituted by a gate electrode that is a portion of the gate line, a channel layer used as a channel, a source electrode and a drain electrode, which are portions of the data line, and a gate insulating layer.

In addition, as high-speed and high-integration of a semiconductor element are rapidly progressing with the development of semiconductor technologies, demands for miniaturization of a pattern and high precision of a pattern dimension are increasing. However, when a length of a channel of the transistor is reduced to reduce a size of the semiconductor element, an effective channel length is reduced due to a short channel effect, and thus, leakage current increases to deteriorate operation characteristics. Thus, research and development for minimizing the size of the semiconductor element by manufacturing a transistor having a three-dimensional structure has been continuously conducted.

In the process of manufacturing the transistor, the channel layer is exposed to an etching gas during a patterning or planarization process. When the channel layer is exposed to the etching gas, an exposed surface of the channel layer is damaged by the etching gas to lose oxygen. In addition, the channel layer is connected to the source electrode and the drain electrode, which are the portions of the data line. Here, when the transistor is driven, oxygen moves from the active layer to the source electrode and the drain electrode, and thus, the active layer loses oxygen. As described above, when oxygen deficiency occurs in the channel layer, the channel layer unintentionally increases in electrical conductivity to function as a electrical conductor. Thus, there is a limitation in that the transistor is not stably driven due to an element short circuit.

### RELATED ART DOCUMENT

### Patent Document

(Patent Document 1) KR10-2004-0013273 A

### SUMMARY

### Technical Problem

The present disclosure provides a method of manufacturing a transistor capable of preventing oxygen deficiency in a channel layer and improving stability at the same time.

### Technical Solution

In accordance with an exemplary embodiment, a method for manufacturing a transistor including a metal line and a channel layer includes: preparing a substrate patterned to expose a first channel layer comprising metal oxide; and forming a second channel layer on an exposed surface of the first channel layer by using at least one of IGZO, IZO, InO, or ZnO.

In the forming of the second channel layer, the second channel layer may be formed in a selective deposition method.

The selective deposition method may include at least one of a selective deposition method and a selective chemical deposition method.

The method may further include: forming an insulating layer to be adjacent to the first channel layer; and forming the metal line to be adjacent to the insulating layer.

The method may further include, after forming the second channel layer, forming the metal line.

The metal line may include at least one of a bit line and a word line of a memory element.

In accordance with another exemplary embodiment, a method for manufacturing a transistor including a metal line and a channel layer includes: preparing a substrate patterned to expose the channel layer comprising metal oxide; and forming an electrode on an exposed surface of the channel layer by using at least one of Ru or RuO.

In accordance with yet another exemplary embodiment, a method for manufacturing a transistor including a metal line and a channel layer includes: preparing a substrate patterned to expose the channel layer comprising metal oxide; and forming a treatment layer on an exposed surface of the channel layer.

In the forming of the treatment layer, the exposed surface of the channel layer may be treated through at least one of heat treatment or plasma treatment.

The heat treatment may be performed by supplying an O₂ gas to the exposed surface of the channel layer, and the plasma treatment may be performed by supplying at least one of an O₂ gas or an NF₃ gas to the exposed surface of the channel layer.

### Advantageous Effects

According to the exemplary embodiment, the functional layer for preventing the oxygen deficiency of the channel layer may be formed on the exposed surface of the channel layer to prevent the channel layer from being conducted and improving the switching characteristics.

In addition, the contact resistance between the channel layer and the source and drain electrodes may be effectively reduced, and the characteristics and reliability of the element may be improved.

### BRIEF DESCRIPTION OF THE DRAWINGS

FIG. 1 is a view illustrating an example of a semiconductor element in which a transistor is used, in accordance with an exemplary embodiment;

FIG. 2 is a schematic view illustrating a transistor in accordance with an exemplary embodiment;

FIG. 3 is a schematic view illustrating a transistor in accordance with another exemplary embodiment;

FIGS. 4, 5 and 6 are schematic views illustrating a method for manufacturing a transistor in accordance with an exemplary embodiment; and

FIGS. 7, 8 and 9 are schematic views illustrating a method for manufacturing a transistor in accordance with another exemplary embodiment.

### DETAILED DESCRIPTION OF EXEMPLARY EMBODIMENTS

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art.

It will also be understood that when a layer, a region, or a substrate is referred to as being ‘on’ another one, it can be directly on the other one, or one or more intervening layers, regions, or substrates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the figures, the dimensions of layers and regions may be exaggerated for clarity of illustration. Like reference numerals refer to like elements throughout.

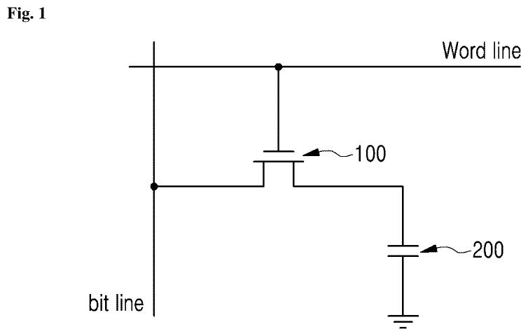

FIG. 1 is a view illustrating an example of a semiconductor element in which a transistor is used, in accordance with an exemplary embodiment.

As illustrated in FIG. 1, a transistor 100 in accordance with an exemplary embodiment may be used in a memory element such as a dynamic random access memory (DRAM). The DRAM is a type of volatile semiconductor memory element generally used in electronic devices such as computers and portable terminals.

The DRAM may include a plurality of memory cells arranged in a plurality of rows and columns. Here, each memory cell may include, for example, one transistor 100 and one capacitor 200.

As described above, the DRAM may include a word lines and a bit line. Here, the word line may be connected to or included in a gate line of the transistor and determine whether the memory cell is used. The bit line may be connected to or included in a source electrode or drain electrode of the transistor and may serve to check a stored memory value (0 or 1).

Hereinafter, a case in which the transistor 100 in accordance with an exemplary embodiment is used in the DRAM is exemplarily described, but the transistor 100 in accordance with an exemplary embodiment is used in not only the DRAM, but also in various circuits for independently driving each cell or pixel in a semiconductor element, a liquid crystal display, and the like.

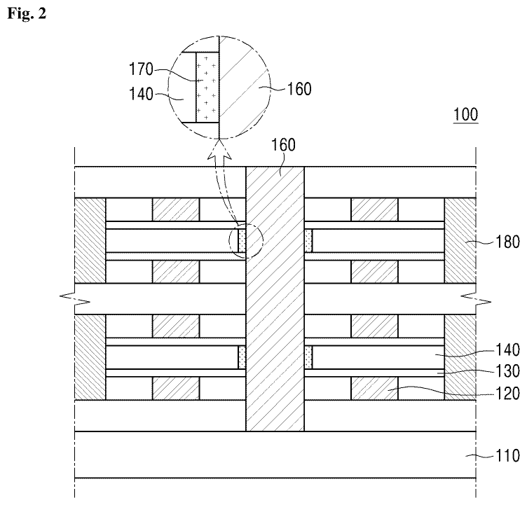

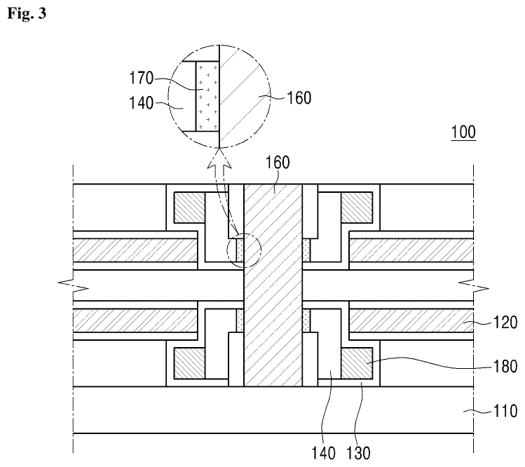

FIG. 2 is a schematic view illustrating a transistor in accordance with an exemplary embodiment, and FIG. 3 is a schematic view illustrating a transistor in accordance with another exemplary embodiment.

A transistor in accordance with an exemplary embodiment may include a metal line, a channel layer, and various other insulating layers. Here, FIG. 2 is a schematic view illustrating a horizontal stacked transistor in accordance with an exemplary embodiment, and FIG. 3 is a schematic view illustrating a vertical stacked transistor in accordance with another exemplary embodiment. In addition, FIGS. 2 and 3 are cross-sectional views taken along a plane in a stacking direction in accordance with exemplary embodiments.

First, referring to FIG. 2, a transistor 100 in according to an exemplary embodiment may include a substrate 110, a word line 120 provided on the substrate 110, a gate insulating layer 130 provided on the word line 120, a first channel layer 140 provided on the gate insulating layer 130, a gate insulating layer 130 provided on the first channel layer 140, and a word line 120 provided on the gate insulating layer 130. In addition, the transistor 100 in accordance with an exemplary embodiment may include a gate insulating layer 130 and a bit line 160 provided to pass through the first channel layer 140. In addition, the transistor 100 may further include a capacitor line 180 provided outside the word line 120 so as to be connected to the first channel layer 140 and various insulating layers disposed between each layer and each line. Here, the metal line in accordance with an exemplary embodiment may include at least one of the word line 120, the bit line 160, or the capacitor line 180.

The substrate 110 may be made of a material including silicon (Si). An insulating layer may be formed on the substrate 110, and the word line 120 serving as a gate electrode in the transistor 100 may be formed on the insulating layer. Although the word line 120 and the bit line 160 are disposed on both sides with respect to the bit line 160 in FIG. 2, this represents a cross-sectional shape, and in a three-dimensional structure, the word line 120 may have a ring shape as a whole. The word line 120 may be made of a material having electrical conductivity, for example, at least one metal of aluminum (Al), neodymium (Nd), silver (Ag), chromium (Cr), titanium (Ti), tantalum (Ta), or molybdenum, or an alloy thereof. The insulating layers may be disposed inside and outside the word line 120.

The gate insulating layer 130 may be disposed on the word line 120. As described above, the gate insulating layer 130 may be made of one or more insulating materials of inorganic insulating layers including silicon oxide (SiO₂), silicon nitride (SiN), alumina (Al₂O₃), and zirconia (ZrO₂) having excellent adhesion to metal materials and excellent dielectric strength.

The first channel layer 140 may be formed on the gate insulating layer 130. The first channel layer 140 may be made of metal oxide. Here, the first channel layer 140 may be formed as a metal oxide thin film or a plurality of metal oxide thin films having different compositions. For example, the first channel layer 140 may include oxide including at least one of indium (In), gallium (Ga), or zinc (Zn).

For example, indium (In) may be a metal having a relatively low band gap and a relatively high standard electrode potential and thus may have characteristics of increasing in charge concentration and improving mobility. On the other hand, gallium (Ga) may be a metal having a relatively high band gap and a relatively low standard electrode potential and thus may have characteristics of reducing a charge concentration and improving stability. Thus, the electrical conductivity of the first channel layer 140 may be adjusted by controlling contents of indium (In) and gallium (Ga) contained in the metal oxide thin film. As described above, the first channel layer 140 provided as the metal oxide thin film has a characteristic in which the electrical conductivity decreases as the oxygen content increases, and the electrical conductivity increases as the oxygen content decreases.

The gate insulating layer 130 may be formed on the first channel layer 140, and the word line 120 having the ring shape as a whole may be formed on the gate insulating layer 130. Although the structure in which two stacks formed as described above are disposed with an interlayer insulating layer therebetween is illustrated in FIG. 2, the number of stacks stacked with the interlayer insulating layer therebetween may be variously changed.

The bit line 160 may serve as a source electrode in the transistor 100 and may be provided to pass through the gate insulating layer 130, the first channel layer 140, and other insulating layers inside the word line 120. The bit line 160 may be formed by forming a hole inside the word line 120 to pass through the gate insulating layer 130, the first channel layer 140, and other insulating layers and may be formed by filling the inside of the formed hole with an electrically conductive material. The above-described bit line 160 may be made of, for example, a conductive material, for example, at least one metal of aluminum (Al), neodymium (Nd), silver (Ag), chromium (Cr), titanium (Ti), tantalum (Ta), or molybdenum, or an alloy thereof.

The capacitor line 180 serving as a drain electrode of the transistor 100 may be formed outside the word line 120. For example, the capacitor line 180 may be formed to have a shape surrounding the word line 120, which are respectively disposed below and above the first channel layer 140. The above-described capacitor line 180 may be made of a conductive material, for example, at least one metal of aluminum (Al), neodymium (Nd), silver (Ag), chromium (Cr), titanium (Ti), tantalum (Ta), or molybdenum, or an alloy thereof.

In the transistor 100 in accordance with an exemplary embodiment, the second channel layer 170 is formed on the exposed surface of the first channel layer 140. For example, in the transistor 100 in accordance with an exemplary embodiment, as illustrated in FIG. 2, the second channel layer 170 may be formed between the first channel layer 140 and the bit line 160. However, the formation position of the second channel layer 170 is not limited thereto, and the second channel layer 170 may be formed on various exposed surfaces, on which the first channel layer 140 is exposed, before the bit line 160 and the capacitor line 180 are formed.

The second channel layer 170 may be made of at least one of In—Ga—Zn—O (IGZO), In—Zn—O (IZO), InO, or ZnO. When the second channel layer 170 is not formed, and the metal line is formed to be connected to the first channel layer 140, the first channel layer 140 may be exposed by the etching gas while the stack is patterned to form the metal line. When the first channel layer 140 is exposed by the etching gas, the first channel layer 140 may be damaged by the etching gas from the exposed surface to a predetermined depth to lose oxygen and then become an oxygen deficiency state. In addition, when the metal line is directly formed on the surface of the first channel layer 140, which is damaged by the etching gas, oxygen moves from the first channel layer 140 to the metal line when the transistor is driven. As described above, when the oxygen deficiency occurs in the first channel layer 140, the first channel layer 140 may unintentionally increase in electrical conductivity to be conductive, and an element short circuit may occur so that the transistor is not stably driven.

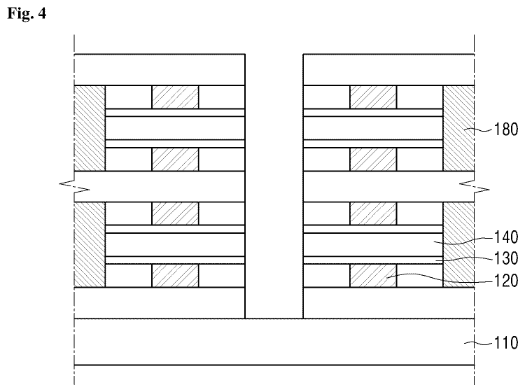

In contrast, when the second channel layer 170 made of at least one of IGZO, IZO, InO, or ZnO is formed between the first channel layer 140 and the metal line as in the exemplary embodiment, the first channel layer 140 is formed, oxygen or a metal material contained in the second channel layer 170 may be filled into a position of the first channel layer 140 from which oxygen is escaped. That is, the metal element or oxygen contained in the second channel layer 170 is diffused into the position of the first channel layer 140, from which oxygen is escaped, to prevent oxygen from moving from the first channel layer 140 to the metal line and prevent the first channel layer 140 from being conductive. A method of forming the second channel layer 170 between the first channel layer 140 and the metal line will be described later with reference to FIGS. 4 to 6.

Referring to FIG. 3, a transistor 100 in accordance with another exemplary embodiment may include a substrate 110, a word line 120 provided on the substrate 110, a first channel layer 140 provided inside the word line 120 to extend in a vertical direction, and a gate insulating layer 130 provided to cover the first channel layer 140. In addition, the transistor 100 in accordance with another exemplary embodiment may include a bit line 160 provided to pass through the first channel layer 140 and the gate insulating layer 130. In addition, the transistor 100 may further include a capacitor line 180 provided inside the gate insulating layer 130 so as to be connected to the first channel layer 140 and various insulating layers disposed between each layer and each line. Here, the metal line in accordance with an exemplary embodiment may include at least one of the word line 120, the bit line 160, or the capacitor line 180 as described above.

The substrate 110 may be made of a material containing silicon (Si), an insulating layer may be formed on the substrate 110, and the word line 120 serving as a gate electrode in the transistor 100 may be formed on the insulating layer. The word line 120 may be made of a material having electrical conductivity, for example, at least one metal of aluminum (Al), neodymium (Nd), silver (Ag), chromium (Cr), titanium (Ti), tantalum (Ta), or molybdenum, or an alloy thereof. An insulating layer may be provided on the word line 120 as described above.

The first channel layer 140 and the gate insulating layer 130 are formed inside the word line 120. For example, the first channel layer 140 may be provided along a portion of a circumference of the bit line 160 that passes through the word line 120 and the insulating layer. In addition, a barrier layer may be formed between the first channel layer 140 and the bit line 160 so that the first channel layer 140 is spaced apart from the bit line 160 except for a portion of a surface that is in contact with the bit line 160. In addition, the second channel layer 170 connected to the first channel layer 140 is provided above the word line 120. Here, the first channel layer 140 and the second channel layer 170 may be covered by the gate insulating layer 130. Here, the transistor 100 in accordance with another exemplary embodiment may have a layered structure different from that of the transistor 100 in accordance with an exemplary embodiment described above, but the function of each layer may be the same. Thus, descriptions duplicated with those described above with respect to the transistor 100 in accordance with an exemplary embodiment will be omitted.

In the transistor 100 in accordance with another exemplary embodiment, the second channel layer 170 may be also formed on the exposed surface of the first channel layer 140. For example, in the transistor 100 in accordance with another exemplary embodiment, as illustrated in FIG. 3, the second channel layer 170 may be formed between the first channel layer 140 and the bit line 160. However, the formation position of the second channel layer 170 is not limited thereto, and as described above, the second channel layer 170 may be formed on various exposed surfaces, on which the first channel layer 140 is exposed, before the bit line 160 and the capacitor line 180 are formed.

The second channel layer 170 may be made of at least one of In—Ga—Zn—O (IGZO), In—Zn—O (IZO), InO, or ZnO. When the second channel layer 170 is not formed, and the metal line is formed to be connected to the first channel layer 140, the first channel layer 140 may be exposed by the etching gas while the stack is patterned to form the metal line. When the first channel layer 140 is exposed by the etching gas, the first channel layer 140 may be damaged by the etching gas from the exposed surface to a predetermined depth to lose oxygen and then become an oxygen deficiency state. In addition, when the metal line is directly formed on the surface of the first channel layer 140, which is damaged by the etching gas, oxygen moves from the first channel layer 140 to the metal line when the transistor is driven. As described above, when the oxygen deficiency occurs in the first channel layer 140, the first channel layer 140 may unintentionally increase in electrical conductivity to be conductive, and an element short circuit may occur so that the transistor is not stably driven.

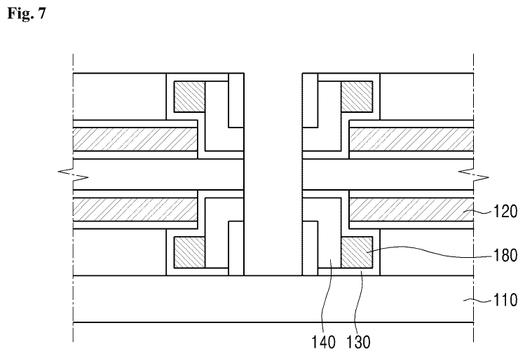

In contrast, when the second channel layer 170 made of at least one of IGZO, IZO, InO, or ZnO is formed between the first channel layer 140 and the metal line as in the exemplary embodiment, the first channel layer 140 is formed, oxygen or a metal material contained in the second channel layer 170 may be filled into a position of the first channel layer 140 from which oxygen is escaped. That is, the metal element or oxygen contained in the second channel layer 170 is diffused into the position of the first channel layer 140, from which oxygen is escaped, to prevent oxygen from moving from the first channel layer 140 to the metal line and prevent the first channel layer 140 from being conductive. A method of forming the second channel layer 170 between the first channel layer 140 and the metal line will be described later with reference to FIGS. 7 to 9.

Although the second channel layer 170 is formed on the exposed surface of the first channel layer 140 to prevent the first channel layer 140 from being conductive in FIGS. 2 and 3, the conductivity of the first channel layer 140 may be prevented by forming an electrode or treatment layer on the exposed surface of the first channel layer 140.

That is, in the transistor having the metal line and the channel layer, an electrode made of at least one of Ru or RuO may be formed on the exposed surface of the channel layer including the metal oxide, or the exposed surface of the channel layer may be treated with at least one of heat or plasma to form a treatment layer, thereby prevent the channel layer from being conductive.

FIGS. 4 to 6 are schematic views illustrating a method for manufacturing a transistor in accordance with an exemplary embodiment, and FIGS. 7 to 9 are schematic views illustrating a method for manufacturing a transistor in accordance with another exemplary embodiment.

Referring to FIGS. 4 to 9, a method for manufacturing a transistor in accordance with exemplary embodiments is a method for manufacturing a transistor having a metal line and a channel layer and includes a process of preparing a substrate that is patterned to expose a first channel layer 140 including metal oxide and a process of forming a second channel layer 170 on the exposed surface of the first channel layer 140 by using at least one IGZO, IZO, InO, or ZnO.

First, a method for manufacturing a transistor in accordance with an exemplary embodiment will be described with reference to FIGS. 4 to 6.

In a process of preparing a patterned substrate 110, as illustrated in FIG. 4, a patterned substrate is prepared to expose a first channel layer 140 including metal oxide. Here, the patterned substrate may include a substrate 110, a word line 120 provided on the substrate 110, a gate insulating layer 130 provided on the word line 120, a first channel layer 140 provided on the gate insulating layer 130, a gate insulating layer 130 provided on the first channel layer 140, and a word line 120 provided on the gate insulating layer 130.

A hole for forming a bit line 160 is formed in the patterned substrate 110, and the first channel layer 140 is exposed through the hole. Here, an area on which the first channel layer 140 is exposed toward the hole is defined as the exposed surface of the first channel layer 140.

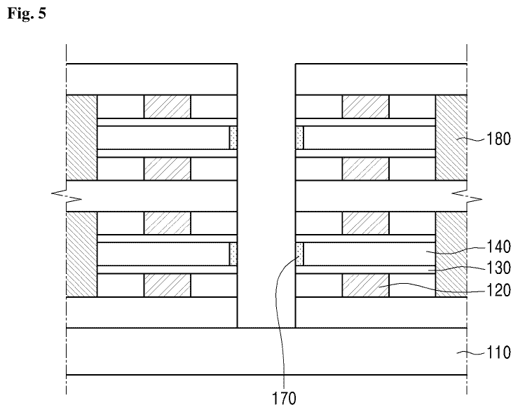

When the patterned substrate 110 is prepared, as illustrated in FIG. 5, a second channel layer 170 is formed on the exposed surface of the first channel layer 140 by using at least one of IGZO, IZO, InO, or ZnO. The second channel layer 170 may be formed by various thin film formation processes. For example, the process of forming the second channel layer 170 may be performed by a chemical vapor deposition (CVD) method, in which a source gas including a metal element and a reaction gas including oxygen are supplied at the same time on the exposed surface of the first channel layer 140, and an atomic layer deposition (ALD) method, in which a process cycle including a process of supplying the source gas including the metal element on the exposed surface of the first channel layer 140 and a process of supplying a reaction gas including oxygen on the exposed surface of the first channel layer 140 is repeated several times. Here, the atomic layer deposition process may be performed by repeatedly performing a process cycle, in which the process of supplying the source gas including the metal element, a process of purging the source gas, the process of supplying the reaction gas including oxygen, and a process of purging the reaction gas are sequentially performed, several times.

In the process of forming the second channel layer 170, the second channel layer 170 may be formed by a selective deposition method. Here, the selective deposition method means a method of selectively depositing a thin film only on a surface of a specific area. Here, the selective deposition method may include at least one of an area selective-chemical vapor deposition (AS-CVD) method and an area selective-atomic layer deposition (AS-ALD) method, and the second channel layer 170 may be formed by applying various known selective deposition methods.

In addition, the method of manufacturing the transistor in accordance with an exemplary embodiment may include a process of forming a gate insulating layer 130 to be adjacent to the first channel layer 140 and a process of forming a word line 120 adjacent to the gate insulating layer 130. For example, in accordance with an exemplary embodiment, in the process of preparing the patterned substrate, the gate insulating layer 130 may be formed on the word line 120, the first channel layer 140 may be formed on the gate insulating layer 130, the word line 120 may be formed on the gate insulating layer 130 after forming the gate insulating layer 130 on the first channel layer 140, the gate insulating layer 130 may be formed to be adjacent to the first channel layer 140, and the word line 120 may be formed to be adjacent to the gate insulating layer 130.

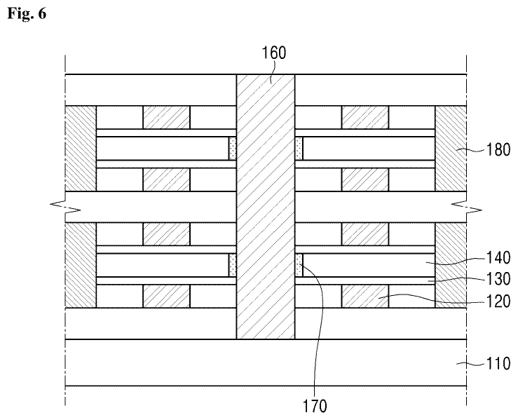

After forming the second channel layer 170, as illustrated in FIG. 6, a conductive material may be filled into a hole provided to pass through the gate insulating layer 130, the first channel layer 140, and other insulating layers in the word line 120 to form a bit line 160. Although the patterned substrate, on which the capacitor line 180 has already been formed, is used in FIGS. 4 to 6, the capacitor line 180 may be formed after forming the second channel layer 170.

Next, a method for manufacturing a transistor in accordance with another exemplary embodiment will be described with reference to FIGS. 7 to 9.

In a process of preparing a patterned substrate 110, as illustrated in FIG. 7, a patterned substrate is prepared to expose a first channel layer 140 including metal oxide. Here, the patterned substrate may include a substrate 110, a word line 120 provided on the substrate 110, a first channel layer 140 provided inside the word line 120 to extend in a vertical direction, and a gate insulating layer 130 provided to cover the first channel layer 140. In addition, the patterned substrate may further include a capacitor line 180 provided inside the gate insulating layer 130 so as to be connected to the first channel layer 140.

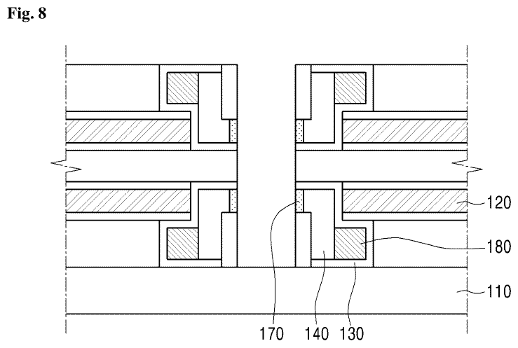

When the patterned substrate 110 is prepared, as illustrated in FIG. 8, a second channel layer 170 is formed on the exposed surface of the first channel layer 140 by using at least one of IGZO, IZO, InO, or ZnO. The second channel layer 170 may be formed by various thin film formation processes. For example, the process of forming the second channel layer 170 may be performed by a chemical vapor deposition (CVD) method, in which a source gas including a metal element and a reaction gas including oxygen are supplied at the same time on the exposed surface of the first channel layer 140, and an atomic layer deposition (ALD) method, in which a process cycle including a process of supplying the source gas including the metal element on the exposed surface of the first channel layer 140 and a process of supplying a reaction gas including oxygen on the exposed surface of the first channel layer 140 is repeated several times. Here, the atomic layer deposition process may be performed by repeatedly performing a process cycle, in which the process of supplying the source gas including the metal element, a process of purging the source gas, the process of supplying the reaction gas including oxygen, and a process of purging the reaction gas are sequentially performed, several times.

In the process of forming the second channel layer 170, the second channel layer 170 may be formed by a selective deposition method. Here, the selective deposition method means a method of selectively depositing a thin film only on a surface of a specific area. Here, the selective deposition method may include at least one of an area selective-chemical vapor deposition (AS-CVD) method and an area selective-atomic layer deposition (AS-ALD) method, and the second channel layer 170 may be formed by applying various known selective deposition methods.

In addition, the method of manufacturing the transistor in accordance with another exemplary embodiment may include a process of forming a gate insulating layer 130 to be adjacent to the first channel layer 140 and a process of forming a word line 120 adjacent to the gate insulating layer 130. For example, in the process of preparing the patterned substrate in another exemplary embodiment, the gate insulating layer 130 may be formed to cover the first channel layer 140 in a circumferential direction of a hole for forming a bit line 160, and the word line 120 may be formed outside the gate insulating layer.

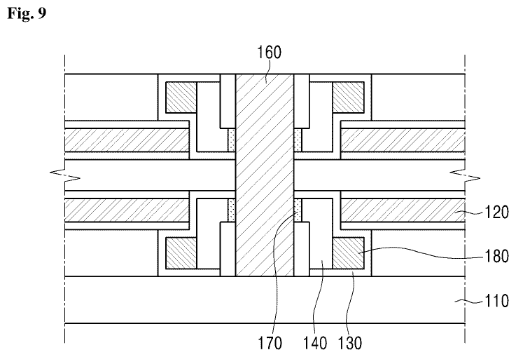

After forming the second channel layer 170, as illustrated in FIG. 9, a conductive material may be filled in the hole to pass through the first channel layer 140 and the gate insulating layer 130, thereby forming the bit line 160. Although the patterned substrate, on which the word line 120 has already been formed, is used in FIGS. 7 to 9, the word line 120 may be formed after forming the second channel layer 170.

Although the second channel layer 170 is formed on the exposed surface of the first channel layer 140 to prevent the first channel layer 140 from being conductive in FIGS. 4 and 9, the conductivity of the first channel layer 140 may be prevented by forming an electrode or treatment layer.

Here, the process of forming the electrode may be the same as the above-described process of forming the second channel layer in that the process of forming the electrode is performed in the chemical vapor deposition or atomic layer deposition method. In addition, the process of forming the electrode may also be formed in the selective deposition method, and the selective deposition method may include at least one of the selective chemical vapor deposition method or the selective atomic layer deposition method.

In the process of forming the treatment layer, the exposed surface of the channel layer may be treated using at least one of heat or plasma to form a treatment layer. Here, when the exposed surface of the channel layer is thermally treated, an O₂ gas may be supplied to the exposed surface to thermally treat the channel layer, and when the exposed surface of the channel layer is treated using the plasma, at least one of O₂ or NF₃ may be supplied to the exposed surface to plasma-treat the channel layer. For example, when the NF₃ gas is supplied to plasm-treat the channel layer, physical and electrical damage may be minimized, and high selectivity may be secured.

In accordance with the exemplary embodiments, the functional layer for preventing the oxygen deficiency of the channel layer may be formed on the exposed surface of the channel layer to prevent the channel layer from being conducted and improving the switching characteristics.

In addition, the contact resistance between the channel layer and the source and drain electrodes may be effectively reduced, and the characteristics and reliability of the element may be improved.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

What is claimed is:

1. A method for manufacturing a transistor comprising a metal line and a channel layer, the method comprising:
preparing a substrate patterned to expose a first channel layer comprising metal oxide; and
forming a second channel layer on an exposed surface of the first channel layer by using at least one of IGZO, IZO, InO, or ZnO.

2. The method for manufacturing the transistor of claim 1, wherein, in the forming of the second channel layer, the second channel layer is formed in a selective deposition method.

3. The method for manufacturing the transistor of claim 2, wherein the selective deposition method comprises at least one of a selective deposition method and a selective chemical deposition method.

4. The method for manufacturing the transistor of claim 1, further comprising:
forming an insulating layer to be adjacent to the first channel layer; and
forming the metal line to be adjacent to the insulating layer.

5. The method for manufacturing the transistor of claim 1, further comprising, after forming the second channel layer, forming the metal line.

6. The method for manufacturing the transistor of claim 1, wherein the metal line comprises at least one of a bit line and a word line of a memory element.

7. A method for manufacturing the transistor comprising a metal line and a channel layer, the method comprising:
preparing a substrate patterned to expose the channel layer comprising metal oxide; and
forming an electrode on an exposed surface of the channel layer by using at least one of Ru or RuO.

8. A method for manufacturing a transistor comprising a metal line and a channel layer, the method comprising:
preparing a substrate patterned to expose the channel layer comprising metal oxide; and
forming a treatment layer on an exposed surface of the channel layer.

9. The method for manufacturing the transistor of claim 8, wherein, in the forming of the treatment layer, the exposed surface of the channel layer is treated through at least one of a heat treatment or a plasma treatment.

10. The method for manufacturing the transistor of claim 9, wherein the heat treatment is performed by supplying an O₂ gas to the exposed surface of the channel layer, and
the plasma treatment is performed by supplying at least one of an O₂ gas or an NF₃ gas to the exposed surface of the channel layer.
